(19) United States
(12) Patent Application Publication
(10) Pub. No.: US 2025/0191812 A1
(43) Pub. Date: Jun. 12, 2025

(54) HERMETICALLY SEALED HIGH-TEMPERATURE SUPERCONDUCTING TAPE CONDUCTOR

(71) Applicant: Theva Dünnschichttechnik GmbH, Ismaning (DE)

(72) Inventor: Werner PRUSSEIT, Ismaning (DE)

(73) Assignee: Theva Dünnschichttechnik GmbH, Ismaning (DE)

(21) Appl. No.: 18/844,096

(22) PCT Filed: Mar. 13, 2023
(86) PCT No.: PCT/EP2023/056323

§ 371 Date: Sep. 5, 2024

(30) Foreign Application Priority Data
Mar. 14, 2022 (EP) 22161887.9

(51) Int. Cl. H01B 12/02; H01B 13/26

(52) U.S. Cl. CPC H01B 12/02; H01B 13/26

(57) ABSTRACT

A superconductor comprises a high-temperature superconducting tape conductor, HTS tape conductor, and at least one layer of metal foil which is wound around the HTS tape conductor and soldered thereto in a spiral shape in a plurality of windings and thereby forms a reinforcement which hermetically seals the HTS tape conductor. Such a superconductor can be manufactured by a method which comprises the following steps: spiral wrapping an HTS tape conductor with at least one layer of a solder-coated metal foil, heating the metal foil above the melting point of the solder coating and subsequently cooling to below the melting point of the solder coating in order to connect the metal foil to the HTS tape conductor and thereby form a reinforcement which hermetically seals the HTS tape conductor.

### 1. TECHNICAL FIELD

The invention relates to a high-temperature superconducting tape conductor (HTS tape conductor) which is hermetically sealed against environmental influences by a metal foil wound around the HTS tape conductor in a spiral shape in a plurality of windings.

### 2. PRIOR ART

HTS tape conductors are used in technology for transporting high currents, for example in cables and busbars, for generating high magnetic fields in analytics or medical technology, for beam guidance in accelerators or for plasma confinement in fusion reactors. In addition, the rapid, dynamic transition from the lossless superconducting state to the normally conducting state in the event of overload can be used for rapid switches and for current limiters.

In many of these fields of use, the HTS tape conductors are cooled by immersion into a liquid, cryogenic medium such as liquid nitrogen (boiling point at 77 K), liquid hydrogen (boiling point at 21 K), neon (boiling point at 27 K) or liquid helium (boiling point at 4.2 K).

Modern HTS tape conductors (so-called 2. Generation or 2G) comprise a flexible metal substrate which is coated with the HTS material used by chemical or physical methods.

This usually originates from the so-called 123 material class with the composition RBa₂Cu₃O₇, where R denotes an element or a mixture of elements from the group of the rare earths (for example Gd, Eu, Dy, Hf) or yttrium (Y). Since the HTS coating typically takes place at high temperatures (for example at T>650° C.), the HTS coating cannot be applied directly to the metal foil. Depending on the production method used, different intermediate layers, so-called buffer layers, are used which, on the one hand, act as a diffusion barrier, on the other hand, impart a crystallographic orientation or adapt parameters of the crystal lattice for the epitaxy of the HTS layer. Both the deposition of the buffer layers and of the HTS layer(s) can take place using different methods, for example chemically by so-called metal-organic deposition (MOD) of an amorphous precursor material (precursor) which is calcined by temperature treatment and crystallized into the desired phase, by metal-organic chemical vapor deposition (MOCVD), or different physical vacuum coating methods (PVD).

During conversion and during growth of the HTS layers and/or of the buffer layers, cavities can occur in the layer package. The formation of cavities is particularly pronounced when column-like growth of the layers occurs, such as, for example, in so-called inclined substrate deposition (ISD). In this method, an oriented buffer layer (usually composed of MgO) is generated by vapor deposition of the material at a high deposition rate and at an angle obliquely with respect to the substrate surface (cf., for example, EP 0 909 340). As a result, a so-called forest of columns is formed which widen and grow together with increasing layer thickness. Although the MgO layer appears closed at its surface, it is therefore penetrated by vertical intermediate spaces.

However, in other methods, such as MOD, cavities are often formed in the layers by solid-state reactions. In addition, the HTS tape conductors are often cut to narrower tapes in the course of the production process proceeding from a relatively large strip width. In this case, the layer package is exposed at the cut edge. In addition, cracks can be formed which run into the layers from the side.

In further production steps, the HTS tape conductors are usually still encased with thin metal layers composed of silver (Ag) or copper (Cu). Thus, for example, galvanic methods can be used to deposit Cu layers having a typical thickness of 5-20 μm (cf. JP 07335051 or EP 1 639 609). These circumferential metal layers serve for protection, for electrical stabilization and for feeding current into the underlying HTS layer. However, such Ag or Cu layers are also rarely 100% free of damage, holes or channels. In particular at the edge, i.e. at a cut edge, the adhesion of such layers is often reduced and the layers can be easily scraped off and thus opened (for example by scraping on guide rollers during production).

If such HTS tape conductors are immersed for several hours in a cryogenic liquid bath, the cooling liquid slowly seeps into the existing cavities. This is intensified by air present in the cavities being condensed below 77 K and a negative pressure thereby being formed which intensifies the infiltration of the cooling liquid by capillary forces. Under normal circumstances, this infiltration of cooling liquid into the layers of the HTS strip conductor does not lead to an impairment of the function of the superconductor.

However, if the HTS strip conductor is warmed up rapidly, for example by lifting it rapidly out of the cooling liquid, or if strong local warming occurs as a result of a so-called quench, the cooling liquid present in the cavities can evaporate abruptly, which is accompanied by a 700-1000-fold change in volume. However, the narrow channels in the layers of the HTS strip conductor, through which the cooling liquid slowly seeps, and the largely closed surfaces of the HTS strip conductor apart therefrom do not permit a rapid escape of gas, with the result that a very high rise in pressure occurs locally, which bursts the surrounding material and/or bulges to form a bubble. This effect is also known as so-called ballooning. During such an event, the HTS strip conductor is irreversibly, mechanically destroyed at this point.

Particularly liquid hydrogen and helium have a very low viscosity and high diffusivity, with the result that even very small openings and accesses are sufficient to infiltrate the underlying cavities.

The behavior described above also occurs in HTS conductors of the 1^{st} generation (1G), which are produced by a metallurgical powder-in-tube (PIT) method. For this purpose, a powder of an HTS material is introduced into a metal tube, pressed, sintered and rolled, with the result that HTS ceramic filaments are formed in a metal matrix. In this method, too, cavities are formed in the HTS filling and cooling liquid can seep in as a result of hair cracks in the metallic matrix. For this purpose, AMSC developed a configuration in which the HTS tape conductor is laminated with a metal foil on both sides and soldered thereto. As a result of an overhang of the foils on both sides, two channels are formed along the conductor, which channels are filled with a solder material and thus form a solder bridge laterally. This arrangement is described in EP 1 203 415. Since the geometries of 1G and 2G tape conductors are similar, this method is likewise suitable for 2G HTS tape conductors. A similar method for laminating an HTS tape conductor with thermoplastic plastic films on both sides is described in WO 2013/004392 A1.

A further method for packaging an HTS tape conductor has been developed by Fujikura and is described in EP 2 940 699 and EP 2 770 513. In this case, a solder-coated metal foil with twice the width of the HTS tape conductor is folded around the HTS tape conductor along its axis and soldered thereto, such that the front side and edges are completely covered. In this case, the seam on the rear side of the conductor can also be filled with solder, such that infiltration of cooling liquid is no longer possible even from there.

In order to electrically insulate HTS tape conductors without holes, inter alia a method has been developed in which a thin plastic tape is wrapped around the HTS tape conductor. This plastic tape can consist, for example, of polyimide (trade name: Kapton) as described in DE 3 823 938 or of polyester (cf. DE 10 2004 048 439). Polyimide has a low coefficient of thermal expansion and hardly embritts and is therefore particularly suitable for use at cryogenic temperatures.

The methods described above for sheathing HTS tape conductors are used in practice. However, difficulties also arise in this case. The metal tapes used in the prior art are often not ideally straight, but typically have a certain camber, i.e. a deviation from the straight configuration. As a result, the accurate alignment and guidance of three parallel tapes during lamination is problematic, which makes the production of long piece lengths difficult. In fact, the exact position of the internal HTS tape conductor, of the so-called insert relative to the edge of the metal tapes, can hardly be controlled. As a result of lateral offset, the HTS tape conductor can be displaced completely to one side, so that no overhang of the two metal foils and no solder bridge is formed there. The so-called sandwich often bursts at such points and cooling liquid can penetrate into the HTS tape conductor there.

In some applications, such as, for example, a superconducting current limiter, the HTS tape conductor can additionally heat up (>250° C.) as a result of brief overload (quenching) in such a way that the melting temperature of the solder material is reached and the sandwich composite dissolves. In this case, the lamination also no longer constitutes mechanical protection.

When folding over an HTS tape conductor by means of a folded-over metal foil, the latter constitutes at least one mechanically stable clamp which does not become detached even when the solder softens. However, the method is mechanically very demanding and can cause problems at connection points of the HTS tape conductor. Such connection points are significantly thicker—often even twice as thick as the single conductor—as a result of overlapping HTS tape conductors. When folding in, channels and cavities are typically formed here, which channels and cavities are not filled in the case of a typical solder layer of approximately 10 μm.

Even the enveloping with plastic is not suitable for sealing an HTS tape conductor against infiltration of cooling liquids merely on account of the selection of material. In addition, adhesive embritts on the rear side at low temperatures and plastic forms microcracks and has a certain permeability for gases and light elements even in the undamaged state.

The problem on which the present invention is based is therefore to at least partially reduce some of the disadvantages of the prior art described above.

### 3. SUMMARY OF THE INVENTION

The technical problem cited above is at least partially solved by the subject matter of the independent claims of the present invention. Exemplary embodiments are the subject matter of the dependent claims.

In one embodiment, the present invention provides a superconductor which has an HTS tape conductor and at least one layer of metal foil which is wound around the HTS tape conductor and soldered thereto in a spiral shape in a plurality of windings and thereby forms a reinforcement which hermetically seals the HTS tape conductor.

The term superconductor is to be understood technically in the context of the present application, specifically in the sense of a piece of electrical conductor which has superconducting properties. Furthermore, the inventors are aware that, instead of soldering, which is clearly to be preferred on account of the substantially better electrical, thermal and mechanical properties—in particular at cryogenic temperatures—it would also be possible to use other connection techniques such as, for example, adhesive bonding with an epoxy adhesive which may have good thermal conductivity, in order to produce the bond between HTS tape conductor and metal foil. Therefore, such alternative superconductors are likewise part of the present invention.

In particular, the metal foil may comprise pure or low-alloy Cu or Al and/or have a thickness between 10 μm and 100 μm, preferably between 20 μm and 50 μm. Alternatively or additionally, a solder layer which has a melting point below 280° C., preferably below 250° C., and a thickness between 2 μm and 30 μm, preferably between 5 μm and 15 μm, may be applied to at least one surface of the metal foil.

Such a hermetic reinforcement thereby forms an electrically conductive, mechanically stable sheathing of the HTS tape conductor, which sheathing is well coupled to the HTS layer and is hermetically sealed, in particular, against the slow infiltration of typical cooling liquids (LH₂, LHe, LN₂, etc.), which sheathing at least partially eliminates the disadvantages of the prior art discussed above.

Such a superconductor can be manufactured, for example, by the method specified in the independent method claim.

Such a method and the construction principle specified above address, in particular, the problems described above as a result of the winding of the HTS tape conductor with a metallic foil which can be reliably applied even via joints and unevennesses and is self-aligned during winding. For this purpose, the HTS tape conductor is wrapped, for example, with a ductile metal foil. Said metal foil may be coated with a thin layer composed of solder material which, after the wrapping, is soldered firmly to the HTS tape conductor surfaces under the action of heat and pressure.

The metal foil (or the metal strip) with which the HTS tape conductor is wrapped should preferably have, on the one hand, a slight plastic deformability but, on the other hand, also a sufficient tensile strength in order not to tear off with moderate tensile stresses of, for example, 10-150 MPa during the winding over the strip edges. Metals such as copper, aluminum, silver, nickel, tin, lead, indium and others which are very ductile in the pure state or with a low content of added-alloy constituents or can be annealed soft by heat treatment after rolling to form a thin foil appear to be highly suitable. Copper, aluminum and silver, optionally with a low proportion of alloying additives or else a soft bronze, are particularly preferred for the technical application. The selection of material is also determined here by the application-specific requirements for the electrical conductivity, the heat conduction and the heat capacity.

The above-described spiral wrapping of the HTS tape conductor with a metal foil avoids the disadvantages of existing methods and furthermore has, inter alia, a series of advantages for the production. Thus, the metal foil forms a mechanically firm reinforcement around the internal, wrapped HTS tape conductor.

Thus, two or more HTS tape conductors and/or one or more additional metal tapes could also lie in the interior as an insert and thus form a composite conductor. Connection points, patches and regions of variable thickness are also reliably encased by the wrapping. The method is also tolerant with regard to a possible camber of the insert, is self-aligning and adapts itself to a certain bend within the tolerances as a result of slight offset. For example, the tolerable camber lies below 5 mm/m (deviation from the straight line). In addition, the claimed spiral wrapping technology can be used sequentially a number of times in order to achieve absolutely reliable sealing or a desired thickness of the end product. For this purpose, it is recommended to wind the second layer in the same direction and with offset to form a gap, so that the joints of the first layer are reliably covered.

In particular, the heating and/or the cooling can take place under the action of a contact pressure, the heating preferably takes place by the wrapped HTS tape conductor being guided through hot rollers or through a hot caterpillar.

For example, after the wrapping, the HTS tape conductor can be guided through hot rollers or a heated caterpillar which melt the solder and press the composite onto one another when the latter cools. As a result, firm soldering of the materials is achieved. In addition, excess solder runs as a result of capillary forces also into the joints between the loops of the wrapping and fills the latter.

In some embodiments, during the wrapping, a rotation frequency and an advance of the wrapping can be set up such that the windings of the at least one layer of metal foil lie close to one another without overlap and in an abutting manner. This leads to improved shielding against environmental influences, a surface which is as homogeneous as possible and/or an additional thickness of the superconductor which is as small as possible.

Alternatively or additionally, during the wrapping, a rotation frequency and an advance of the wrapping can be set such that a pitch angle of the windings is less than 45° and preferably lies between 20° and 30°.

As a result, for example, superconductors can be manufactured in which the metal foil wraps around the HTS tape conductor at an angle of less than 45°, preferably at an angle between 20° and 30°, with respect to the width of the HTS tape conductor and/or in which the windings of the at least one layer of metal foil lie close to one another without overlap and in an abutting manner.

If, for example, W denotes the width of the HTS tape conductor and B denotes the width of the metal foil to be wound, the rotation frequency and tape advance can be set such that, during each rotation, an offset by a metal foil width B takes place and thus a spiral-shaped sheathing of the HTS tape conductor is formed in an abutting manner.

The pitch angle D thus results from the relationship sin φ=B/2W. This should not become too steep and preferably lies below φ<45°, particularly preferably in the range between 20°-30°, such that W and B assume similar values.

This has, inter alia, the advantage that a hermetic seal can be manufactured simply and rapidly and in this case the resulting superconductor has a thickness which is as small as possible and nevertheless a hermetically tight seal.

It has been shown that it may be advantageous in some applications that, during the wrapping, the at least one layer of metal foil is held under a tensile stress between 10 MPa to 100 MPa. As a result, it can be achieved that the metal foil bears closely against the HTS tape conductor and can be soldered well, but does not tear off there during the wrapping of the strip edges.

As already addressed above, in some embodiments, the method described here can comprise the following additional steps: sequentially spiral wrapping the HTS tape conductor with a plurality of layers of metal foil which are offset with respect to one another, wherein the offset preferably amounts to at least 20% and more preferably substantially half a strip width of the metal foil. In particular, in this case each layer can be soldered individually.

In this way, the quality of the reinforcement and/or of the hermetic seal can be significantly improved.

In further embodiments, a plurality of HTS tape conductors can be connected one above the other or longitudinally and the resulting connected HTS tape conductor can subsequently be wrapped. In this way, the above-described advantages of the present invention can also be applied to superconductors with a substantially higher current-carrying capacity without the production methods and/or the machines which are necessary for this having to be modified to a great extent.

In particular, in some embodiments, a plurality of HTS tape conductors can form a multilayer composite with one another or can be connected in an overlapping manner at their ends and can be wound together with the metal foil and soldered thereto.

In some embodiments, the adhesive strength of the metal foil on the HTS tape conductor can be greater than 10 MPa when the metal foil is peeled in a direction which lies normal to a surface of the HTS tape conductor.

The adhesive strength can preferably be determined via an adhesive peel measurement according to DIN EN ISO 4624:2016. In the case of HTS tape conductors, this measurement method can also expediently be modified to the extent that the strip width necessitates a deviation from the indicated anvil diameter (7 mm). For example, a narrower anvil can also be used in the case of a 4 mm strip width. By contrast, the anvil specified in the standard can be used in the case of a 12 mm strip width.

As addressed above, the reliable adhesion of the wrapping can preferably be ensured with an adhesive peel measurement. For this purpose, a wrapped tape conductor piece is adhesively bonded with the rear side in a plane-parallel manner to a planar base. The end face of a cylindrical anvil is likewise adhesively bonded in a plane-parallel manner to the metal wrapping on the front side. The other side of the anvil is clamped in a tensile testing machine in such a way that the tensile force acts axially with respect to the cylinder on the tape conductor surface and no tilting of the anvil occurs. Measured with this method, the adhesive strength of the metal foil on the insert is preferably above 10 MPa (10 N/mm²). Owing to the spiral wrapping of the HTS tape conductor, the adhesion is not only determined by the soldering, but part of the force is also dissipated into the metal foil, with the result that the mechanical tensile strength thereof likewise contributes to the adhesive strength. The wrapping thus constitutes a mechanically very robust arrangement.

Furthermore, in order also to improve the quality of the seal and reinforcement, the one or the plurality of connected HTS tape conductors can be wrapped with at least one further layer of metal foil, so that the connection points of the windings of the first layer are covered by the further layer, and/or
the one or the plurality of connected HTS tape conductors can comprise an enveloping Cu or Ag layer which has a thickness greater than 2 μm and preferably between 2 μm and 5 μm.

The invention described here therefore leads to hermetically sealed superconductors with greatly improved mechanical, electrical and thermal properties, which can be manufactured simply and reliably in different dimensions and shapes. The present invention therefore makes an important contribution to making HTS tape conductor technology suitable for practice.

### 4. DESCRIPTION OF THE FIGURES

Certain aspects of the present invention are described below with reference to the attached figures. These figures show:

FIG. 1a: a schematic HTS tape conductor structure in cross section before wrapping;

FIG. 1b: a schematic HTS tape conductor structure in cross section after wrapping according to one embodiment of the present invention;

FIG. 2: an illustration of an HTS tape conductor wrapped with metal foil according to one embodiment of the present invention;

FIG. 3: an illustration of an HTS tape conductor with double wrapping with offset according to one embodiment of the present invention;

FIG. 4: an illustration of a double-layer HTS tape conductor wrapped with metal foil according to one embodiment of the present invention; and

FIG. 5: an illustration of a multilayer composite tape conductor wrapped with metal foil according to one embodiment of the present invention.

FIG. 6: Flow diagram of the method steps for producing a reinforced HTS tape conductor.

### 5. DETAILED DESCRIPTION OF SOME EXEMPLARY EMBODIMENTS

Some exemplary feature combinations are described below with reference to some exemplary embodiments of the present invention. Naturally, not all features of the described embodiments must be present in order to implement the present invention. Furthermore, embodiments can be modified by combining certain features of one embodiment with one or more features of another embodiment-if this is technically compatible and meaningful-without departing from the disclosure and the scope of protection of the present invention, which is defined solely by the patent claims.

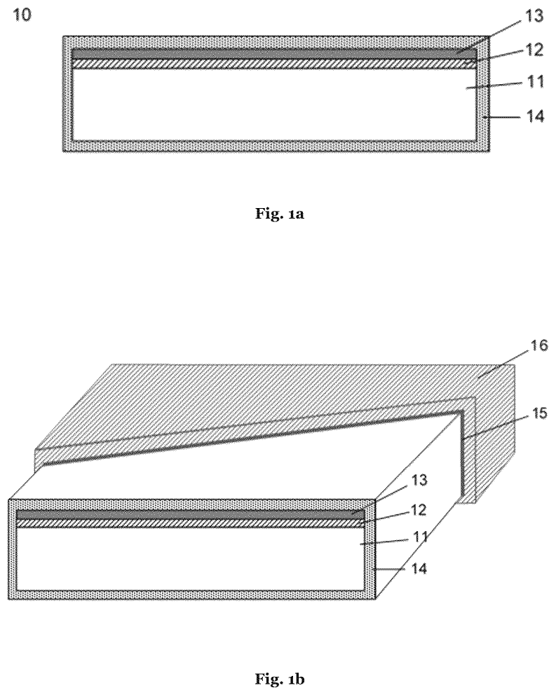

FIG. 1a shows the construction of an HTS tape conductor 10 based on a thin metal substrate 11, preferably an NiCr alloy such as Hastelloy C276, alloys composed of Ni with W or Mo, or a sufficiently alloyed, stainless steel. The thickness preferably lies in the range of 30-150 μm, particularly preferably between 50 and 100 μm. At least one main surface of the metal substrate is coated with one or more buffer layers 12, for example MgO, CeO2, Y2O3, LaMnO3 and/or LaZrO3, on which the HTS functional layer 13 is deposited. This essentially comprises a compound from the group RBa₂Cu₃O₇, where R denotes an element or a mixture of elements from the group of the rare earths (for example Gd, Eu, Dy, Hf) or yttrium (Y). Metal oxides other than impurities such as, for example, BaMO3, where M stands for elements such as Zr, Hf, Ce, Sn, etc., can also be added to this in order to increase the magnetic field strength of the HTS layer. The HTS tape conductor can be enveloped with a thin layer composed of Ag. This can also be intensified by a likewise enveloping Cu layer. The two enveloping metal layers 14 act, on the one hand, as contact layers for feeding current, impart adhesion on the substrate edges and the rear side, and enable the soldering of the HTS tape conductor. The enveloping Ag and/or Cu layer have a total thickness of at least 2 μm, preferably between 2-5 μm, so that they do not dissolve completely by alloying with the solder during the subsequent soldering process. In addition, the HTS tape conductor can also be provided with a thin solder layer, for example PbSn, InAg, SAC solder or other soft solders with a melting point below 280° C., which improves the subsequent wetting during soldering.

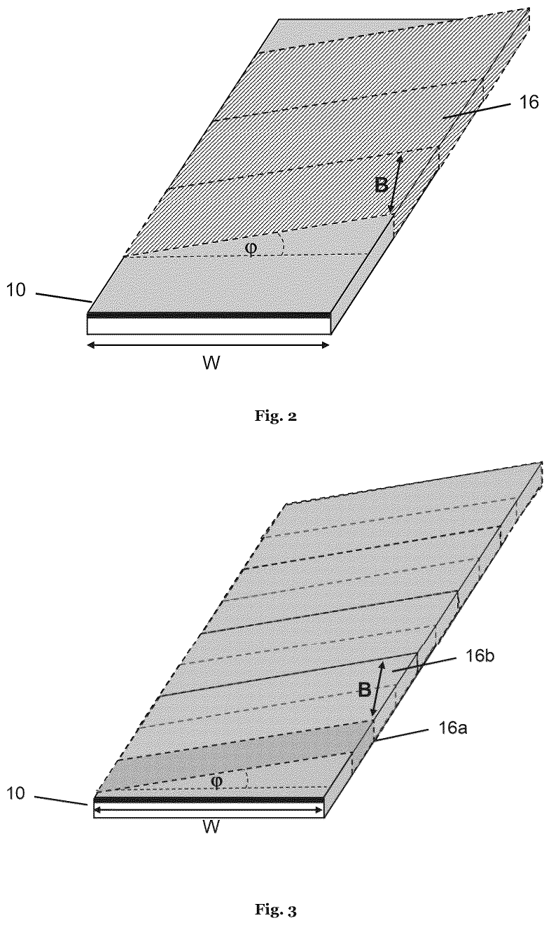

In order to hermetically seal the HTS tape conductor, said tape conductor, as described in detail above and shown in FIGS. 1b and 2, is wrapped firmly with a preferably ductile metal foil 16. Metals such as copper, aluminum, silver, nickel, tin, lead, indium or bronze are very highly suitable for this. Copper, aluminum and silver, optionally with a low proportion of alloying additives and a thin layer of soft solder 15, with a melting point below 280° C., preferably below 250° C., are particularly preferred.

The tensile stress with which the metal strip is wound during the production of the superconductor, depending on the material, lies in the range of 10-150 MPa, the pitch angle φ preferably lies below 45°, particularly preferably in the range between 20°-30°. Subsequently, the wrapped HTS tape can be guided over hot rollers or through a hot caterpillar, wherein the solder material 15 is melted and the composite is compressed. Alternatively or additionally, the melting can also take place by a hot-air blower or an infrared radiator. As likewise discussed above, a contact pressure is preferably used here.

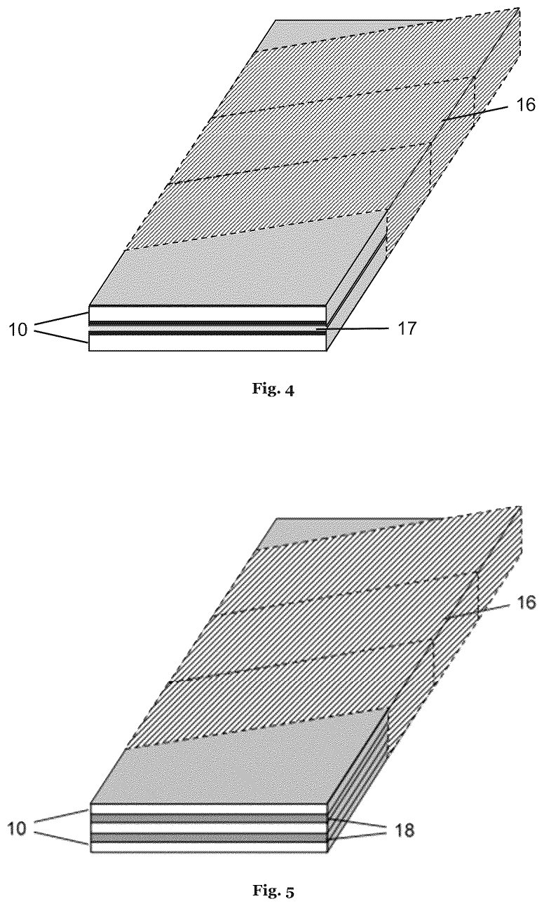

The process of wrapping and soldering can also be repeated a number of times in succession in order to set a specific target thickness of the composite product. This arrangement is shown by way of example in FIG. 3. Preferably, a second layer or further layers of metal foil are wound in the same direction with an offset between the winding layers by at least 20% of the strip width B, particularly preferably approximately half a strip width B, to form a gap, so that the joints of the windings of the layer lying thereunder are reliably covered. A further embodiment relates to an HTS tape conductor (insert) with connection points.

Very long tape conductors with a length of several hundred meters or even more than a thousand meters and a high current-carrying capacity are preferably produced by connecting shorter tape pieces. Ideally, these are practically invisible to the end user and behave like the normal, simple HTS tape conductor. Suitable connection methods are described, for example, in U.S. Pat. No. 7,701,148 or EP 2 835 838. The latter also describes the repair of a defect similar to EP 2 689 477. During the connection, the HTS tape conductors are firstly mechanically connected, for example welded or soldered, to the substrate. In order to ensure the current flow via the joint or via a local defect, a second tape conductor with a facing HTS side (face-to-face) is soldered onto the HTS side of the tape conductor surface as a patch.

This configuration is illustrated in FIG. 4. This bridging is generally significantly thicker than the individual HTS tape conductor. EP 2 835 838 therefore describes how the substrate can be selectively detached from the patch in order to keep this bridging as thin as possible. In any case, however, the connection or repair point constitutes a sensitive region in which the mechanical properties also differ significantly from those of the normal HTS tape conductor.

Thus, the stiffness increases with the third power of the tape thickness and, during transport via rollers, such points like to be bent or spliced and delaminated on account of the abrupt change in the bending stiffness. The present invention permits such patches or connection points to be wrapped or bandaged. This is shown in FIG. 4 and constitutes an additional mechanical reinforcement which holds the assembly together even with strong bending, reliably hermetically seals the transition and makes such points practically invisible to the outside.

A further embodiment relates to an insert which has a plurality of HTS tape conductors 10 which are connected, for example soldered, either to the HTS layer sides (face-to-face) or at the rear sides (back-to-back), or has a combination of HTS tape conductors and metal foils which are soldered to one another via the main faces 17.

In the first case, the superconducting current-carrying capacity can be increased as a result, wherein the range of fluctuation of the current-carrying capacity is likewise reduced (current sharing).

By means of such an assembly of HTS tape conductors and additionally introduced metal foils or intermediate layers 18, as outlined in FIG. 5, certain properties such as the normal electrical conductivity or the heat capacity can additionally be adapted in a targeted manner. This assembly can be mechanically reinforced and hermetically sealed simply or, as shown in FIG. 3, a number of times by the metal foil.

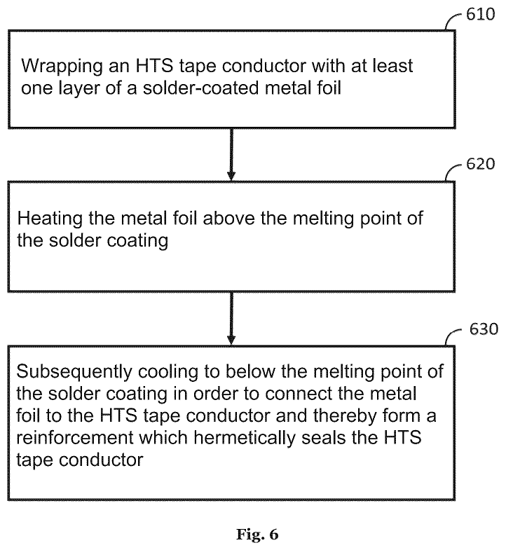

FIG. 6 shows a flow diagram of a production method according to one embodiment of the present invention. In a first step 610, an HTS tape conductor or a plurality of HTS tape conductors connected to one another—as described above—are wound with at least one layer of metal foil. Subsequently, the metal foil is heated to above the melting point of the solder coating 620. Finally, the metal foil is again cooled to below the melting point of the solder coating 630 in order to connect the metal foil to the HTS tape conductor and thereby form a reinforcement which hermetically seals the HTS tape conductor.

Further embodiments of such a production method are described in detail above, in particular in section 3.

### REFERENCE SIGN LIST

10 HTS tape conductor (insert)
11 metal substrate
12 buffer layer(s)
13 HTS layer
14 enveloping, thin metal layer
15 solder layer between HTS tape conductor and metal foil
16, 16a Metal foil-1. wound layer
16b Metal foil-2. wound layer
17 solder layer between HTS tape conductors
18 intermediate layers in the composite conductor
W HTS tape conductor width
B Metal foil width
φ Pitch angle of the windings of the metal foil

1. A superconductor comprising:
a high-temperature superconducting, HTS, tape conductor, and
at least one layer of metal foil which is wound around the HTS tape conductor and soldered thereto in a spiral shape in a plurality of windings and thereby forms a reinforcement which hermetically seals the HTS tape conductor.

2. The superconductor according to claim 1,
wherein the metal foil comprises pure or low-alloy Cu or Al; and/or wherein the
metal foil has a thickness between 10 μm and 100 μm, preferably between 20 μm and 50 μm; and/or
wherein a solder layer which has a melting point below 280° C., preferably below 250° C., and a thickness between 2 μm and 30 μm, preferably between 5 μm and 15 μm, is applied to at least one surface of the metal foil.

3. The superconductor according to claim 1,
wherein the metal foil wraps around the HTS strip conductor at an angle of less than 45°, preferably at an angle between 20° and 30°, with respect to the width of the HTS strip conductor; and/or
wherein the windings of the at least one layer of metal foil lie close to one another without overlap and in an abutting manner.

4. The superconductor according to claim 1, wherein the adhesive strength of the metal foil on the HTS strip conductor is greater than 10 MPa when the metal foil is peeled in a direction which lies normal to a surface of the HTS strip conductor, preferably determined via an adhesive peel measurement according to DIN EN ISO 4624:2016.

5. The superconductor according to claim 1, further comprising:
a plurality of HTS tape conductors which form a multilayer composite with one another or are connected in an overlapping manner at their ends and are wound together with the metal foil and soldered thereto.

6. The superconductor according to claim 1,
wherein the one or the plurality of connected HTS tape conductors are wound with at least one further layer of metal foil, so that the connection points of the windings of the first layer are covered by the further layer; and/or
wherein the one or the plurality of connected HTS tape conductors comprise an enveloping Cu or Ag layer which has a total thickness greater than 2 μm and preferably between 2 μm and 5 μm.

7. A method for manufacturing a superconductor comprising:
spiral wrapping an HTS tape conductor with at least one layer of a solder-coated metal foil;
heating the metal foil above the melting point of the solder coating; and
subsequently cooling to below the melting point of the solder coating in order to connect the metal foil to the HTS tape conductor and thereby form a reinforcement which hermetically seals the HTS tape conductor.

8. The method according to claim 7, wherein the heating and/or the cooling takes place under the action of a contact pressure, the heating preferably by the wrapped HTS tape conductor being guided through hot rollers or through a hot caterpillar.

9. The method according to claim 7, wherein, during the wrapping, a rotation frequency and an advance of the wrapping are set up such that the windings of the at least one layer of metal foil lie close to one another without overlap and in an abutting manner.

10. The method according to claim 7, wherein, during the wrapping, a rotation frequency and an advance of the wrapping are set such that a pitch angle of the windings is less than 45° and preferably lies between 20° and 30°.

11. The method according to claim 7, wherein, during the wrapping, the at least one layer of metal foil is held under a tensile stress between 10 MPa to 100 MPa.

12. The method according to claim 7, further comprising:
sequentially wrapping the HTS tape conductor with a plurality of layers of metal foil which are offset with respect to one another, wherein the offset preferably amounts to at least 20% and more preferably substantially half a strip width of the metal foil.

13. The method according to claim 12, wherein each layer is soldered individually.

14. The method according to claim 7, further comprising
connecting a plurality of HTS tape conductors one above the other or longitudinally; and
subsequently wrapping the connected HTS tape conductors.

15. The method according to claim 7,
wherein the metal foil comprises pure or low-alloy Cu or Al; and/or wherein the
metal foil has a thickness between 10 μm and 100 μm, preferably
between 20 μm and 50 μm; and/or
wherein the solder coating is applied to at least one surface of the metal foil and has a melting point below 280° C., preferably below 250° C., and a thickness between 2 μm and 30 μm, preferably between 5 μm and 15 μm.
